(19) United States
(12) Patent Application Publication
(10) Pub. No.: US 2010/0301728 A1
(43) Pub. Date: Dec. 2, 2010

(54) LIGHT SOURCE HAVING A REFRACTIVE ELEMENT

(75) Inventors: Rene Helbing, Livermore, CA (US); Keith Scott, Livermore, CA (US); Jason Posselt, Livermore, CA (US)

Correspondence Address: Arent Fox LLP, 555 West Fifth Street, 48th Floor, Los Angeles, CA, 90013, US

(73) Assignee: Bridgelux, Inc., Livermore, CA (US)

(21) Appl. No.: 12/766,710

(22) Filed: Apr. 23, 2010

Related U.S. Application Data
(60) Provisional application No. 61/183,320, filed on Jun. 2, 2009.

(51) Int. Cl. H01J 61/52; H01K 1/30; H01J 1/62; H01L 33/08

(52) U.S. Cl. 313/46; 313/110; 313/498; 257/89; 257/E33.067

(57) ABSTRACT

A light emitting apparatus includes a substrate, a plurality of solid state light emitting cells having a planar arrangement on the substrate, and a refractive element arranged with the solid state light emitting cells so that light emitted from the light source has a substantially spherical emission pattern. The refractive element may also be arranged with the solid state light emitting cells to mix the emitted light.

### CROSS-REFERENCE TO RELATED APPLICATION

Pursuant to 35 U.S.C. §119(e), this application claims the benefit of U.S. Provisional Application Ser. No. 61/183,320 filed on Jun. 2, 2009, the contents of which is hereby incorporated by reference in its entirety.

### BACKGROUND

1. Field

The present disclosure relates to light sources, and more particularly to a light source with a refractive element.

2. Background

Solid state devices, such as light emitting diodes (LED)s, are attractive candidates for replacing conventional light sources such as incandescent, halogen and fluorescent lamps. LEDs have substantially higher light conversion efficiencies than incandescent and halogen lamps and longer lifetimes than all three of these types of conventional light sources. In addition, some types of LEDs now have higher conversion efficiencies than fluorescent light sources and still higher conversion efficiencies have been demonstrated in the laboratory. Finally, LEDs require lower voltages than fluorescent lamps and contain no mercury or other potentially dangerous materials, therefore, providing various safety and environmental benefits.

The typical LED has a lambertian emission pattern. This means that light emitted from the LED typically spans a hemispherical arc. This emission pattern may limit the use of LED light sources, or other solid state lighting devices, as replacements for conventional light sources for incandescent, halogen and fluorescent lamps, which emit light in all directions. An LED light source that is used in an incandescent light bulb, for example, may result in undesired dark spots in the downward direction. In common lighting applications, such as desk, floor, or table lamps, this can result in no downward light to enable work or reading tasks.

Accordingly, there is a need in the art for a solid state light source that has an emission pattern that better resembles conventional incandescent, halogen and fluorescent lamps.

### SUMMARY

In one aspect of the disclosure, a light source includes a substrate, a plurality of solid state light emitting cells having a planar arrangement on the substrate, and a refractive element arranged with the solid state light emitting cells so that light emitted from the light source has a substantially spherical emission pattern.

In another aspect of the disclosure, a light source includes a substrate, a plurality of solid state light emitting cells arranged on the substrate to emit light in substantially the same direction, and a refractive element arranged with the solid state light emitting cells so that the light is emitted from the light source has a substantially spherical emission pattern.

In yet another aspect of the disclosure, a light source includes a substrate, a plurality of solid state light emitting cells having a planar arrangement on the substrate, and a refractive element positioned over the solid state light emitting cells so that light emitted from the light source has a substantially spherical emission pattern.

In a further aspect of the disclosure, a light source includes a substrate, a plurality of solid state light emitting cells having a planar arrangement on the substrate, and means for refracting light emitted from the solid state light emitting cells so that the light is emitted from the light source with a substantially spherical emission pattern.

In yet a further aspect of the disclosure, a light source includes a substrate, a plurality of solid state light emitting cells on the substrate, the solid state light emitting cells comprising first and second sets of solid state light emitting cells, wherein each of the solid state light emitting cells in the first set includes a phosphor layer and each of the solid state light emitting cells in the second set does not include a phosphor layer, and a refractive element arranged with the solid state light emitting cells to mix the light emitted from the first and second sets of solid state light emitting cells.

In yet another aspect of the disclosure, a lamp includes a housing having a base and a transparent bulb portion mounted to the base, and a light source within the housing. The light source includes a substrate, a plurality of solid state light emitting cells having a planar arrangement on the substrate, and a refractive element arranged with the solid state light emitting cells so that light emitted from the light source has a substantially spherical emission pattern.

It is understood that other aspects of the present invention will become readily apparent to those skilled in the art from the following detailed description, wherein it is shown and described only exemplary configurations of a light source by way of illustration. As will be realized, the present invention includes other and different aspects of a light source and its several details are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional side view illustrating an example of an LED;

FIG. 2 is a conceptual cross-sectional view illustrating an example of an LED coated with a phosphor material;

FIG. 3A is a conceptual top view illustrating an example of a white light source;

FIG. 3B is a conceptual cross-sectional side view of the white light source in FIG. 3A;

FIG. 4A is a conceptual top view illustrating an example of an alternative configuration of a white light source;

FIG. 4B is a conceptual cross-sectional view of the white light source of FIG. 4A;

FIG. 5 is a conceptual cross-sectional side view illustrating an example of a light source;

FIG. 6 is a conceptual cross-sectional side view illustrating an example of a light source; and

FIG. 7 is a conceptual side view illustrating an example of a lamp with a light source having solid state light emitting cells.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art. The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items

Various aspects of a light source will now be presented. However, as those skilled in the art will readily appreciate, these aspects may be extended to other light sources without departing from the spirit and scope of the invention. The light source may include a substrate, a plurality of solid state light emitting cells arranged on the substrate to form an array of solid state light emitting cells, and a refractive element arranged with the solid state light emitting cells so that light emitted from the light source has a substantially spherical emission pattern. The light source may be used as a direct replacement for conventional light sources currently being used in incandescent, fluorescent, halogen, quartz, high-density discharge (HID), and neon lamps, to name a few.

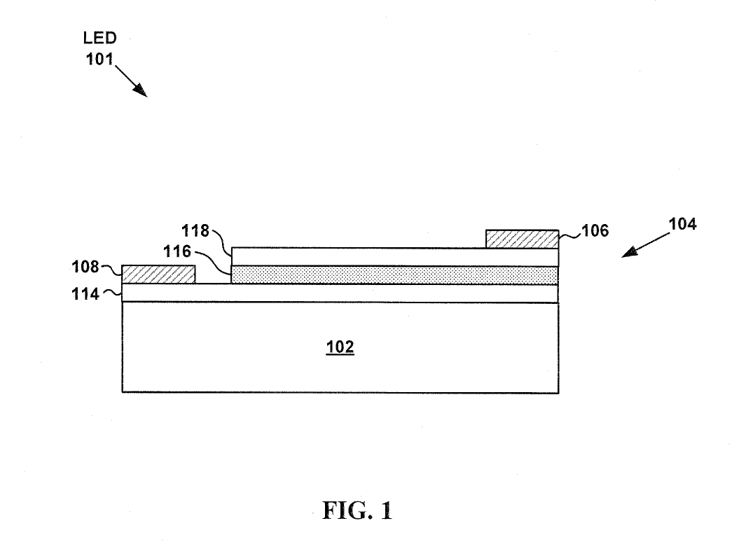

An example of a solid state light emitting cell is an LED. The LED is well known in the art, and therefore, will only briefly be discussed to provide a complete description of the invention. FIG. 1 is a conceptual cross-sectional side view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, which is referred to as n-type or a p-type semiconductor region, respectively. In LED applications, the semiconductor includes an n-type semiconductor region and a p-type semiconductor region. A reverse electric field is created at the junction between the two regions, which cause the electrons and holes to move away from the junction to form an active region. When a forward voltage sufficient to overcome the reverse electric field is applied across the p-n junction, electrons and holes are forced into the active region and combine. When electrons combine with holes, they fall to lower energy levels and release energy in the form of light.

Referring to FIG. 1, the LED 101 includes a substrate 102, an epitaxial-layer structure 104 on the substrate 102, and a pair of electrodes 106 and 108 on the epitaxial-layer structure 104. The epitaxial-layer structure 104 comprises an active region 116 sandwiched between two oppositely doped epitaxial regions. In this example, an n-type semiconductor region 114 is formed on the substrate 102 and a p-type semiconductor region 118 is formed on the active region 116, however, the regions may be reversed. That is, the p-type semiconductor region 118 may be formed on the substrate 102 and the n-type semiconductor region 114 may formed on the active region 116. As those skilled in the art will readily appreciate, the various concepts described throughout this disclosure may be extended to any suitable epitaxial-layer structure. Additional layers (not shown) may also be included in the epitaxial-layer structure 104, including but not limited to buffer, nucleation, contact and current spreading layers as well as light extraction layers.

The electrodes 106 and 108 may be formed on the surface of the epitaxial-layer structure 104. The p-type semiconductor region 118 is exposed at the top surface, and therefore, the p-type electrode 106 may be readily formed thereon. However, the n-type semiconductor region 114 is buried beneath the p-type semiconductor region 118 and the active region 116. Accordingly, to form the n-type electrode 108 on the n-type semiconductor region 114, a portion of the active region 116 and the p-type semiconductor region 118 is removed to expose the n-type semiconductor region 114 therebeneath. After this portion of the epitaxial-layer structure 104 is removed, the n-type electrode 108 may be formed.

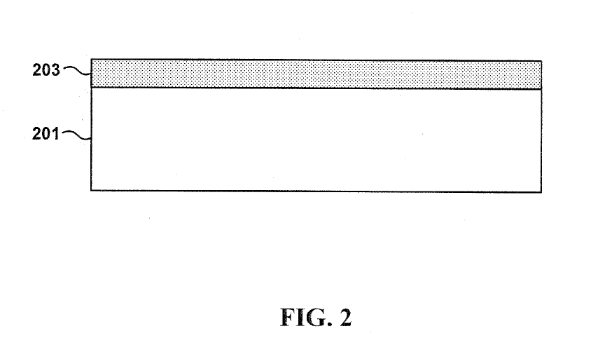

FIG. 2 is a conceptual cross-sectional view illustrating an example of an LED coated with a phosphor material. In this example, a phosphor layer 203 is formed on the top surface of an LED 201 by means well known in the art. In one configuration of an LED, the phosphor layer 203 converts monochromatic light emitted from a blue or ultra-violet (UV) LED 201 to broad-spectrum white light. The present invention, however, may be practiced with other LED and phosphor combinations to produce different color lights. The phosphor layer 203 may include, by way of example, phosphor particles suspended in an epoxy, silicone, or other carrier or may be constructed from a soluble phosphor that is dissolved in the carrier.

One or more phosphor-based blue light LEDs may be arranged in an array to produce a white light source. A white light source may be used as a direct replacement for conventional light sources used today in incandescent, halogen and fluorescent lamps. Alternatively, a white light source may be constructed from individual light emitting LEDs that emit discrete wavelengths (such as red, red orange, orange, green, blue, amber or other colors) and then mix all the colors to produce white light. As those skilled in the art will readily appreciate, various configurations of LEDs and other light emitting cells may be used to create a white light source. Moreover, as noted earlier, the present invention is not limited to solid state lighting devices that produce white light, but may be extended to solid state lighting devices that produce other colors of light.

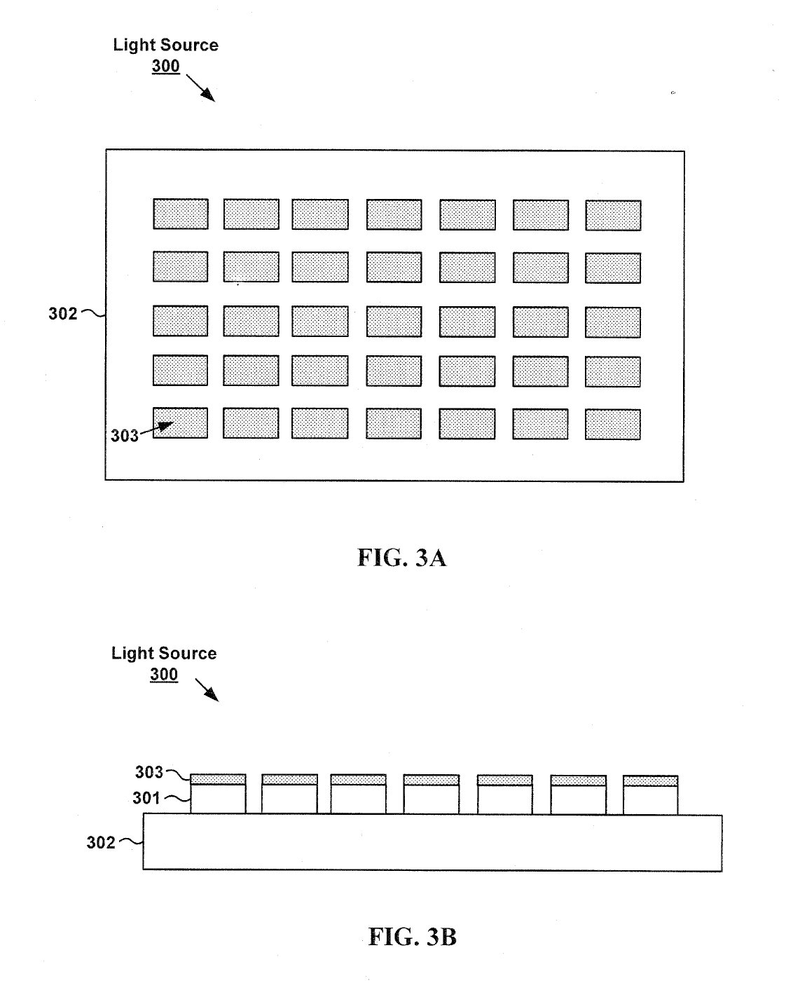

An example of a white light source will now be presented with reference to FIGS. 3A and 3B. FIG. 3A is a conceptual top view illustrating an example of a white light source 300 and FIG. 3B is a conceptual cross-sectional side view of the white light source 300 in FIG. 3A. The white light source 300 may be constructed with multiple LEDs 301 coated with a phosphor material 303. The LEDs 301 may have similar or different outputs (wavelength or power) ad the phosphor material 303 may be similar or different for each LED 301. The LEDs 301 are arranged in a 2-dimensional planar fashion on a substrate 302. The substrate 302 may be made from any suitable material that provides mechanical support to the LEDs 301. Preferably, the material is thermally conductive to dissipate heat away from the LEDs 301. The substrate 302 may include a dielectric layer (not shown) to provide electrical insulation between the LEDs 301. The LEDs 301 may be electrically coupled in parallel and/or series by a conductive circuit layer, wire bonding, or a combination of these or other methods on the dielectric layer.

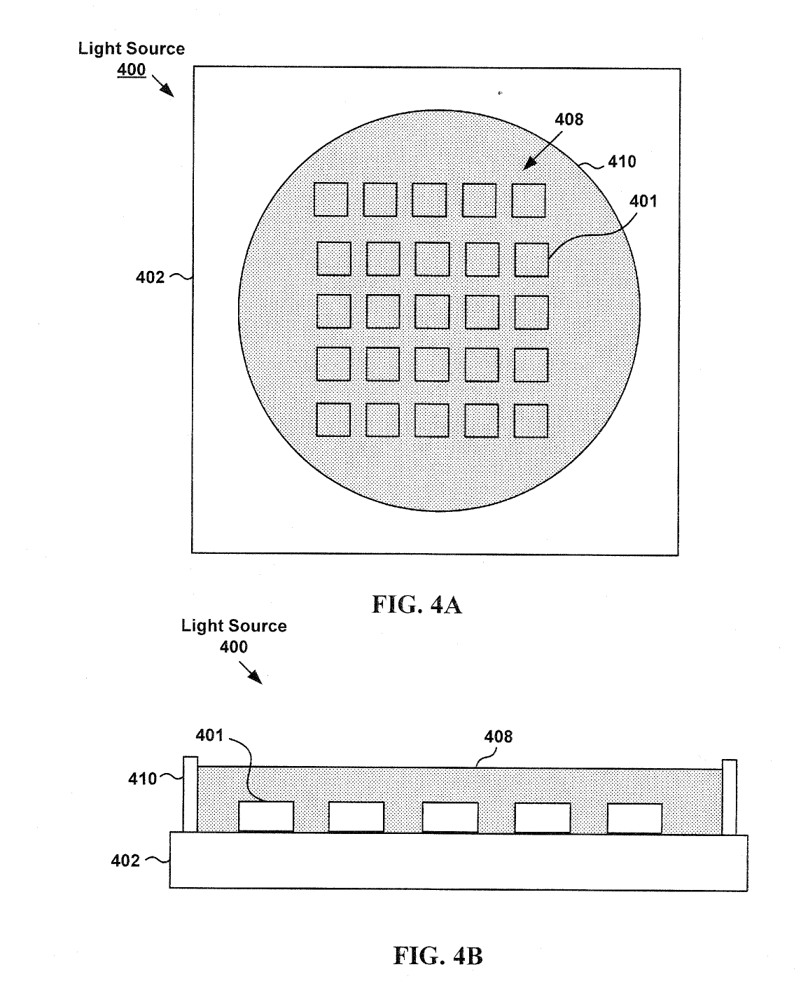

FIG. 4A is a conceptual top view illustrating an example of an alternative configuration of a white light source 400, and FIG. 4B is a conceptual cross-sectional view of the white light source 400 of FIG. 4A. In a manner similar to that described in connection with FIGS. 3A and 3B, a substrate 402 may be used to support an array of LEDs 401. However, in this configuration, a phosphor layer is not formed on each individual LED. Instead, a phosphor material 408 may be deposited within a cavity defined by an annular, or other shaped, boundary 410 that extends circumferentially, or in any other shape, around the upper surface of the substrate 402. The annular boundary 410 may be formed with a suitable mold, or alternatively, formed separately from the substrate 402 and attached to the substrate 402 using an adhesive or other suitable means. A suspension of phosphor particles in a carrier 408 may then be introduced into the cavity. The carrier material may be an epoxy or silicone; however, carriers based on other materials may also be used. The carrier material may be cured to produce a solid material in which the phosphor particles are immobilized.

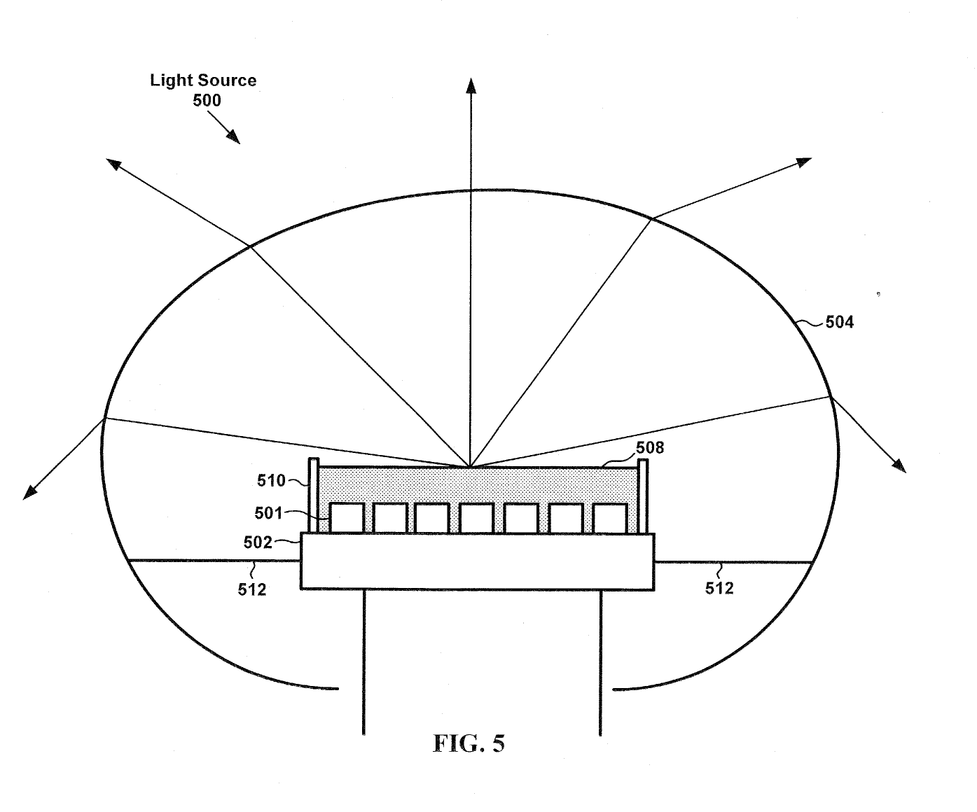

The light source may also be configured with a refractive element in close proximity to the LEDs to produce a substantially spherical emission pattern. An example will now be presented with reference to FIG. 5. FIG. 5 is a conceptual cross-sectional side view illustrating an example of a light source 500. In this example, the light source 500 includes multiple LEDs 501 positioned on a substrate 502. A phosphor material 508 is deposited within a cavity defined by a boundary 510 that extends that extends around the upper surface of the substrate 502. A refractive element 504 may be positioned over the LEDs 501. The refractive element 504 may be attached to the substrate 502 using standoffs 512 or by some other suitable means. The refractive element 504 may be glass, plastic, or any other suitable refractive material having a refractive index different from air. The refractive element 504 is shown as a partial sphere, but may have other shapes. Preferably, the partial sphere is greater than a hemisphere but less than a full sphere in order to capture of all light emitted from the LEDs 501 and direct at least part of the light downward. The result is an emission pattern that is substantially spherical, similar to that of a filament in a conventional incandescent lamp. The combination of the LEDs 501 and the refractive element 504 may be miniaturized by using a high flux density LED source. This miniaturization can enable the same arrangement to be used in a multitude of applications.

The emission pattern may be changed by varying any number of parameters. These parameters include the shape of the refractive element 504 and the position of the refractive element 504 with respect to the LEDs 501. These parameters may be varied to optimize the uniform distribution of light in applications where the light source is intended to be used as a replacement light source in conventional incandescent, halogen and fluorescent lamps. Alternatively, these parameters may be varied to direct more light downwards as may be required in the case of a desk, table, floor or reading lamp or other similar applications. Those skilled in the art will readily be to determine how best to vary these parameters for any particular lighting application based on the teachings presented throughout this disclosure.

Alternatively, a phosphor material may be formed on the interior surface of the refractive element 504 to produce a white light source, thus eliminating the need to deposit the phosphor material directly onto the LEDs 501. By applying the phosphor material to the refractive element 504, the heat generated in the LEDs 501 is reduced, and as a result, the LEDs 501 output more light with improved reliability and longer lifetime. In addition, the heat generated by the phosphor is more widely distributed over the refractive element 504, and therefore, the phosphor will experience less degradation, less color shift, better stability, and more light output. Finally, the light resulting from phosphor scattering that would otherwise be absorbed by the LEDs 501 if it were completely encapsulated by the phosphor is no longer an issue, resulting in increased light output.

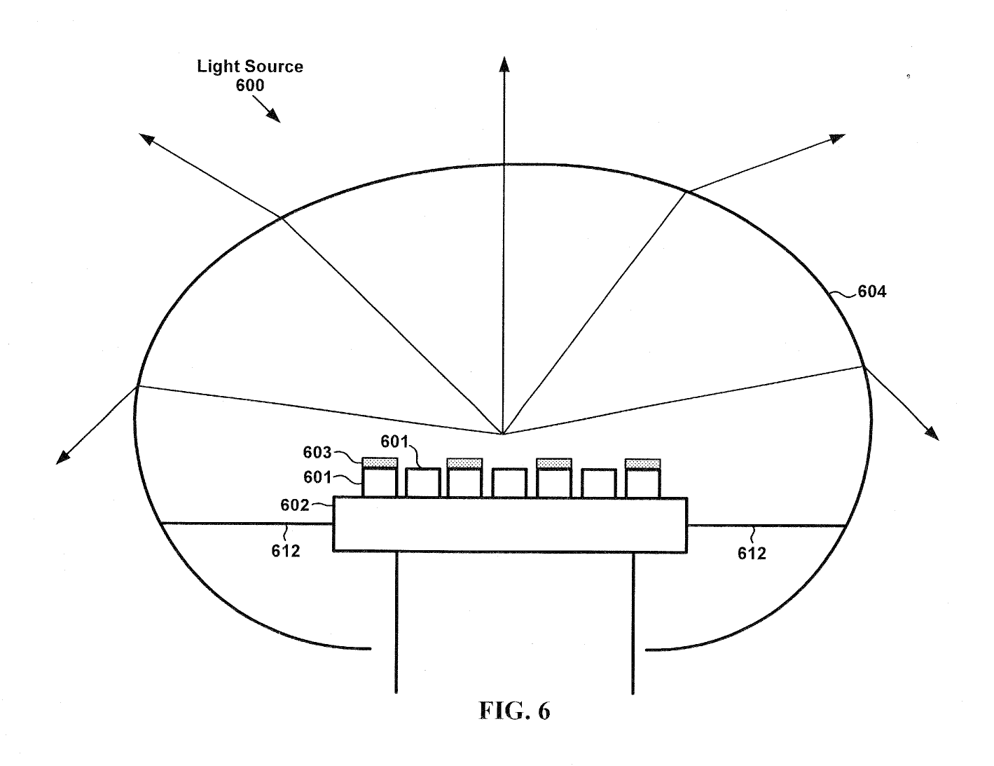

The light source described in connection with FIG. 5 tends to produce a cool white color. Cool white tends to have a blue tint, giving the light a cold feeling. A cool white light source is conducive to outdoor applications that involve cool tones of white. However, when using the light source as a direct replacement for conventional indoor lighting sources, a warmer white similar to the slightly yellowish light given off by an incandescent lamp may be more desirable. Unfortunately, traditional sources that produce a warm white tend have a lower efficacy than those sources that produce a cool white. In one configuration of a light source, a refractive element in close proximity to the LEDs may be used to bridge the efficacy gap between warm and cool light. An example of this configuration will now be presented with reference to FIG. 6. As those skilled in the art will readily appreciate, the various aspects presented in connection with this configuration may be extended to produce different shades of white, as well as other colors of light.

FIG. 6 is a conceptual cross-sectional side view illustrating an example of a light source 600. In this example, the light source 600 may be constructed with multiple LEDs 601 arranged in a 2-dimensional planar fashion on a substrate 602. A first set of LEDs 601 may consist of phosphor coated 603 blue LEDs 601 to produce white light. A second set of LEDs 601 may consist of red, red-orange, orange, amber, or other some other color, or any combination thereof that emit discrete wavelengths. The substrate 602 may be similar to that described earlier in connection with FIG. 3. That is, the substrate 602 may be made from any suitable material that provides mechanical support to the LEDs 601. Preferably, the material is thermally conductive to dissipate heat away from the LEDs 601. The substrate 602 may include a dielectric layer (not shown) to provide electrical insulation between the LEDs 601. The LEDs 601 may be electrically coupled in parallel and/or series by a conductive circuit layer, wire bonding, or a combination of these or other methods on the dielectric layer.

A refractive element 604 may be positioned over the LEDs 601 using standoffs 612 or some other suitable means. As described earlier in connection with FIG. 5, the refractive element 604 may be glass, plastic, or any other suitable refractive material having a refractive index different from air. The refractive element 604 is shown as a partial sphere, which provides a suitable medium for mixing the white light produced by the phosphor coated 603 blue LEDs 601 with the red, red-orange, orange, amber, and/or other color light to produce a warmer white. However, the refractive element 604 may have other shapes. In this example, the partial sphere shape of the refractive element 604 may be used to direct at least part of the warm white light downward. The result is an emission pattern that is substantially spherical, similar to that of a filament in a conventional incandescent lamp.

The shading of light may be changed by varying any number of parameters as described earlier in connection with FIG. 5. These parameters include the shape of the refractive element 604 and the position of the refractive element 604 with respect to the LEDs 601. These parameters may be varied to optimize the uniform distribution of light in applications while providing a warm white light with good efficacy. Those skilled in the art will readily be to determine how best to vary these parameters for any particular lighting application based on the teachings presented throughout this disclosure.

Alternatively, a phosphor material may be formed on the interior surface of the refractive element 604, thus eliminating the need to deposit phosphor directly onto the blue LEDs. In this configuration, the light emitted from the blue LEDs is converted to broad-spectrum white light when it strikes the phosphor coated internal surface of the refractive element. The light emitted from the red, red-orange, orange, amber, and/or other color LEDs, which is unaffected by the phosphor material, is mixed with the white light by the refractive element to produce a warmer white color. The warmer white light is then directed by the refractive element to produce a desired emission pattern. By forming the phosphor material on the interior surface of the refractive element, all the attendant advantages discussed earlier in this disclosure may be realized.

The various configuration of a refractive element described this far may be fabricated by any means known in the art, now known or later developed. The internal surface of the refractive element may have a diffusion coating to better diffuse the light emitted from the LEDs. The internal surface of the refractive element may also be coated with additional material that facilitates heat dissipation. The refractive element may also be formed with multiple apertures (e.g., slits, vents, and/or holes) to further improve the heat dissipation capabilities of the device.

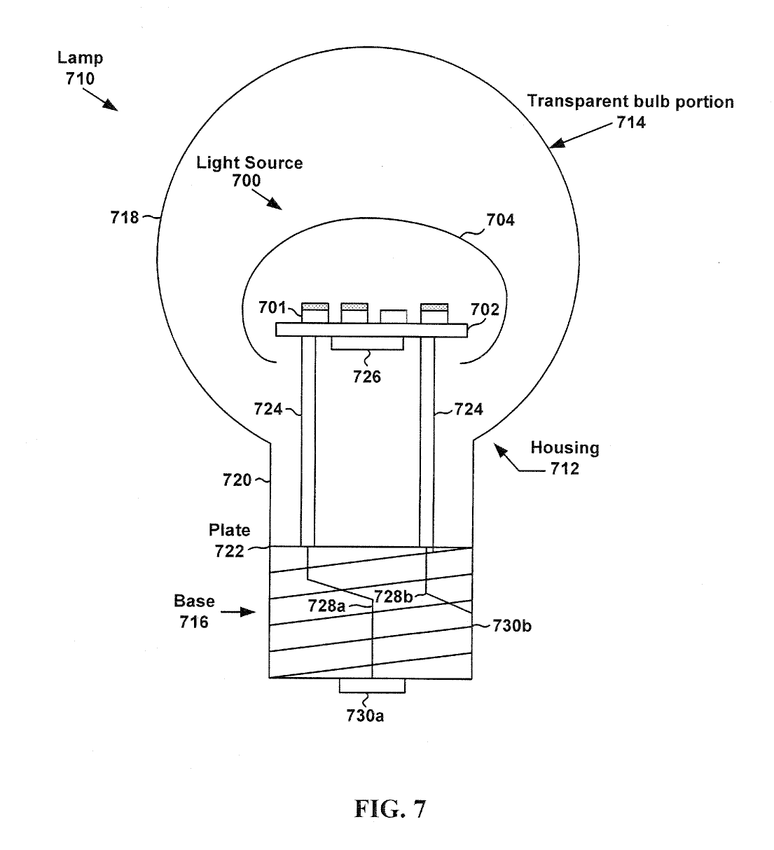

As noted earlier, a light source that produces warm white light with a substantially spherical emission pattern is well suited to function as a replacement light source in conventional incandescent, halogen and fluorescent lamps. An example will now be presented with reference to FIG. 7. FIG. 7 is a conceptual side view illustrating an example of a lamp 710 with a light source 700 having solid state light emitting cells. The lamp 710 may include a housing 712 having a transparent bulb portion 714 (e.g., glass, plastic, etc.) mounted onto a base 716. The transparent bulb portion 714 may be have an internal a diffusion coating to better diffuse the light emitted from the lamp 710. The internal surface of the transparent bulb portion 714 may also be coated with additional material that facilitates heat dissipation. Alternatively, the transparent bulb portion 714 may be filled with a fluid or gas that similarly provides diffusion and/or heat dissipation. The transparent bulb portion 714 is shown with a substantially circular or elliptical portion 718 extending from a neck portion 720, although the transparent bulb portion 714 may take on other shapes and forms depending on the particular application.

A light source 700 may be positioned within the housing 712. The light source 700 may take on various forms, including by way of example, the configurations presented throughout this disclosure, or any other suitable configuration using an arrangement of solid state lighting emitting cells and a refractive element.

A plate 722 anchored to the base 716 provides support for the light source 700. In one configuration of a lamp 710, standoffs 724 extending from the plate 722 are used to separate the light source 700 from the plate 722. The plate 722 may be constructed from any suitable insulting material, including by way of example, glass. In the case of glass, the transparent bulb portion 714 of the housing 712 can be fused to the plate 722 to seal the light source 700.

As discussed earlier, the refractive element 704 may be attached to the substrate 702 by standoffs (not shown). Alternatively, the refractive element 704 may be attached to the plate 722 or some other point in the housing 712.

A fan 726 may be used to cool the light source 700. The fan 726 may be an electronic fan or some other suitable device that generates airflow to cool the light source 700. An electronic fan is a device that generally exploits the concept of corona wind. Corona wind is a physical phenomenon that is produced by a strong electric field. These strong electric fields are often found at the tips of electrical conductors where electric charges, which reside entirely on the surface of the conductor, tend to accumulate. When the electric field reaches a certain strength, known as the corona discharge inception voltage gradient, the surrounding air is ionized with the same polarity as the tip of the conductor. The tip then repels the ionized air molecules surrounding it, thereby creating airflow. A non-limiting example of an electronic fan that exploits corona wind to generate airflow is an RSDS solid-state fan developed by Ventiva or Thorrn Micro Technologies, Inc. The fan 726 may be mounted to the light source 700 as shown in FIG. 7, but may be mounted elsewhere in the housing 712. Those skilled in the art will be readily able to determine the location of the fan best suited for any particular application based on the overall design parameters.

Alternatively, heat pipes may be used to both support the light source 700 above the plate 722 and to dissipate heat away from the light source 700. In connection with the latter function, the heat pipes may be used in conjunction with, or instead of, the fan 726. The heat pipes may extend through a stack of spaced apart thermally conductive horizontal plates in the base 716, which function to dissipate heat away from the heat pipes through multiple vents in the base 716.

The plate 722 also provides a means for routing wires 728a and 728b from the light source 700 to electrical contacts 730a and 730b on the base 716. In one configuration of a lamp 710, the standoffs 724 previously described may be hollow, and the wires 730a and 730b may be routed from the plate 722 to the light source 700 through the hollow standoffs 724. In another configuration of a lamp 710, the wires 728a and 728b themselves can be used to separate the light source 700 from the plate 722, thus eliminating the need for standoffs 724. In the latter configuration, the wires 728a and 728b may be spot welded to feedthrough holes in the plate 722 with another set of spot welded wires extending from the feedthrough holes to the electrical contacts 730a and 730b on the base 716.

The arrangement of electrical contacts 730a and 730b and physical shape of the connecting lamp base may vary depending on the particular application. By way of example, the lamp 710 may have a base 716 with a screw cap configuration, as shown in FIG. 7, with one electrical contact 730a at the tip of the base 716 and the screw cap serving as the other electrical contact 730b. Contacts in the lamp socket (not shown) allow electrical current to pass through the base 716 to the light source 700. Alternatively, the base may have a bayonet cap with the cap used as an electrical contact or only as a mechanical support. Some miniature lamps may have a wedge base and wire contacts, and some automotive and special purpose lamps may include screw terminals for connection to wires. The arrangement of electrical contacts for any particular application will depend on the design parameters of that application.

Power may be applied to the light source 700 and the fan 726 through the electrical contacts 730a and 730b. An AC-DC converter (not shown) may be used to generate a DC voltage from a lamp socket connected to a wall-plug in a household, office building, or other facility. The DC voltage generated by the AC-DC converter may be provided to a driver circuit (not shown) configured to drive both the light source 700 and the fan 726. The AC-DC converter and the driver circuit may be located in the base 716, in the light source 700, or anywhere else in the housing 712. In some applications, the AC-DC converter may not be needed. By way of example, the light source 700 and the fan 726 may be designed for AC power. Alternatively, the power source may be DC, such as the case might be in automotive applications. The particular design of the power delivery circuit for any particular application is well within the capabilities of one skilled in the art.

As discussed in greater detail earlier, a white light source may be constructed with phosphor arranged with multiple light emitting cells. Alternatively, the phosphor material may be formed on the inner surface of transparent bulb portion 714 of the housing 712 to produce a white light source. In another configuration of a lamp, a white light source may be produced by embedding the phosphor material in the transparent bulb portion 714 of the housing 712. These concepts are more fully described in U.S. patent application Ser. No. 12/360,781, entitled “Phosphor Housing for Light Emitting diode Lamp,” the contents of which is incorporated by reference as though fully set forth herein.

The various aspects of this disclosure are provided to enable one of ordinary skill in the art to practice the present invention. Various modifications to aspects presented throughout this disclosure will be readily apparent to those skilled in the art, and the concepts disclosed herein may be extended to other lamp configurations regardless of the shape or diameter of the glass enclosure and the base and the arrangement of electrical contacts on the lamp. By way of example, these concepts may be applied to bulb shapes commonly referred to in the art as A series, B series, C-7/F series, ER, G series, GT, K, P-25/PS-35 series, BR series, MR series, AR series, R series, RP-11/S series, PAR Series, Linear series, and T series; ED17, ET, ET-18, ET23.5, E-25, BT-28, BT-37, BT-56. These concepts may also be applied to base sizes commonly referred to in the art as miniature candela screw base E10 and E11, candela screw base E12, intermediate candela screw base E17, medium screw base E26, E26D, E27 and E27D, mogul screw base E39, mogul Pf P40s, medium skirt E26/50x39, candela DC bay, candela SC bay B15, BA15D, BA15S, D.C. Bayonet, 2-lug sleeve B22d, 3-lug sleeve B22-3, medium Pf P28s, mogul bi-post G38, base RSC, screw terminal, disc base, single contact, medium bi-post, mogul end prong, spade connector, mogul pre-focus and external mogul end prong; admedium skirted, medium skirted, position-oriented mogul, BY 22 D, Fc2, ceramic spade series (J, G, R), RRSC, RSC; single pin series, bi-pin series, G, GX, 2G series. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

1. A light source, comprising:
a substrate;
a plurality of solid state light emitting cells having a planar arrangement on the substrate; and
a refractive element arranged with the solid state light emitting cells so that light emitted from the light source has a substantially spherical emission pattern.

2. The light source of claim 1 further comprising phosphor arranged with the solid state light emitting cells so that the light emitted from the light source is white light.

3. The light source of claim 1 wherein each of the solid state light emitting cells includes a phosphor layer.

4. The light source of claim 1 further comprising a boundary on the substrate, wherein the solid state light emitting cells is arranged within the interior of the boundary, the light source further comprising phosphor deposited within the interior of the boundary.

5. The light source of claim 1 wherein the solid state light emitting cells comprises first and second sets of solid state light emitting cells, wherein each of the solid state light emitting cells in the first set includes a phosphor layer and each of the solid state light emitting cells in the second set does not include a phosphor layer.

6. The light source of claim 5 wherein the refractive element is arranged with the solid state light emitting cells to mix the light emitted from the first and second sets of solid state light emitting cells.

7. The light source of claim 5 wherein each of the light emitting cells in the first set comprises a blue LED and each of the light emitting cells in the second set comprises an LED having that emits a longer wavelength than the blue LEDs.

8. The light source of claim 7 wherein each of the light emitting cells in the second set comprises a red, red-orange, orange or amber LED.

9. The light source of claim 1 wherein the refractive element comprises a surface facing the solid state light emitting cells and a phosphor layer on the surface.

10. The light source of claim 1 wherein the refractive element comprises a diffusion coated surface facing the solid state light emitting cells.

11. The light source of claim 1 wherein the refractive element is attached to the substrate.

12. The light source of claim 1 wherein the refractive element has a refractive index different from air.

13. The light source of claim 1 wherein the refractive element has a partially spherical shape positioned over the solid state light emitting cells.

14. The light source of claim 13 wherein the partially spherical shape of the refractive element is greater than a hemisphere but less than a full sphere.

15. A light source, comprising:
a substrate;
a plurality of solid state light emitting cells arranged on the substrate to emit light in substantially the same direction; and
a refractive element arranged with the solid state light emitting cells so that the light is emitted from the light source with a substantially spherical emission pattern.

16. The light source of claim 15 further comprising phosphor arranged with the solid state light emitting cells so that the light emitted from the light source is white light.

17. The light source of claim 15 wherein each of the solid state light emitting cells includes a phosphor layer.

18. The light source of claim 15 further comprising a boundary on the substrate, wherein the solid state light emitting cells is arranged within the interior of the boundary, the light source further comprising phosphor deposited within the interior of the boundary.

19. The light source of claim 15 wherein the solid state light emitting cells comprises first and second sets of solid state light emitting cells, wherein each of the solid state light emitting cells in the first set includes a phosphor layer and each of the solid state light emitting cells in the second set does not include a phosphor layer.

20. The light source of claim 19 wherein the refractive element is arranged with the solid state light emitting cells to mix the light emitted from the first and second sets of solid state light emitting cells.

21. The light source of claim 19 wherein each of the light emitting cells in the first set comprises a blue LED and each of the light emitting cells in the second set comprises an LED having that emits a longer wavelength than the blue LEDs.

22. The light source of claim 21 wherein each of the light emitting cells in the second set comprises a red, red-orange, orange or amber LED.

23. The light source of claim 15 wherein the refractive element comprises a surface facing the solid state light emitting cells and a phosphor layer on the surface.

24. The light source of claim 15 wherein the refractive element comprises a diffusion coated surface facing the solid state light emitting cells.

25. The light source of claim 15 wherein the refractive element is attached to the substrate.

26. The light source of claim 15 wherein the refractive element has a refractive index different from air.

27. The light source of claim 15 wherein the refractive element has a partially spherical shape positioned over the solid state light emitting cells.

28. The light source of claim 27 wherein the partially spherical shape of the refractive element is greater than a hemisphere but less than a full sphere.

29. A light source, comprising:
a substrate;
a plurality of solid state light emitting cells having a planar arrangement on the substrate; and
a refractive element positioned over the solid state light emitting cells so that light emitted from the light source has a substantially spherical emission pattern.

30. The light source of claim 29 further comprising phosphor arranged with the solid state light emitting cells so that the light emitted from the light source is white light.

31. The light source of claim 29 wherein each of the solid state light emitting cells includes a phosphor layer.

32. The light source of claim 29 further comprising a boundary on the substrate, wherein the solid state light emitting cells is arranged within the interior of the boundary, the light source further comprising phosphor deposited within the interior of the boundary.

33. The light source of claim 29 wherein the solid state light emitting cells comprises first and second sets of solid state light emitting cells, wherein each of the solid state light emitting cells in the first set includes a phosphor layer and each of the solid state light emitting cells in the second set does not include a phosphor layer.

34. The light source of claim 33 wherein the refractive element is arranged with the solid state light emitting cells to mix the light emitted from the first and second sets of solid state light emitting cells.

35. The light source of claim 33 wherein each of the light emitting cells in the first set comprises a blue LED and each of the light emitting cells in the second set comprises an LED having that emits a longer wavelength than the blue LEDs.

36. The light source of claim 35 wherein each of the light emitting cells in the second set comprises a red, red-orange, orange or amber LED.

37. The light source of claim 29 wherein the refractive element comprises a surface facing the solid state light emitting cells and a phosphor layer on the surface.

38. The light source of claim 29 wherein the refractive element comprises a diffusion coated surface facing the solid state light emitting cells.

39. The light source of claim 29 wherein the refractive element is attached to the substrate.

40. The light source of claim 29 wherein the refractive element has a refractive index different from air.

41. The light source of claim 29 wherein the refractive element has a partially spherical shape positioned over the solid state light emitting cells.

42. The light source of claim 41 wherein the partially spherical shape of the refractive element is greater than a hemisphere but less than a full sphere.

43. A light source, comprising:
a substrate;
a plurality of solid state light emitting cells having a planar arrangement on the substrate; and
means for refracting light emitted from the solid state light emitting cells so that the light is emitted from the light source with a substantially spherical emission pattern.

44. The light source of claim 43 further comprising phosphor arranged with the solid state light emitting cells so that the light emitted from the light source is white light.

45. The light source of claim 43 wherein each of the solid state light emitting cells includes a phosphor layer.

46. The light source of claim 43 further comprising a boundary on the substrate, wherein the solid state light emitting cells is arranged within the interior of the boundary, the light source further comprising phosphor deposited within the interior of the boundary.

47. The light source of claim 43 wherein the solid state light emitting cells comprises first and second sets of solid state light emitting cells, wherein each of the solid state light emitting cells in the first set includes a phosphor layer and each of the solid state light emitting cells in the second set does not include a phosphor layer.

48. The light source of claim 47 wherein the means for refracting light comprises a refractive element arranged with the solid state light emitting cells to mix the light emitted from the first and second sets of solid state light emitting cells.

49. The light source of claim 47 wherein each of the light emitting cells in the first set comprises a blue LED and each of the light emitting cells in the second set comprises an LED having that emits a longer wavelength than the blue LEDs.

50. The light source of claim 49 wherein each of the light emitting cells in the second set comprises a red, red-orange, orange or amber LED.

51. The light source of claim 43 wherein the means for refracting light comprises a refractive element having a surface facing the solid state light emitting cells and a phosphor layer on the surface.

52. The light source of claim 43 wherein the means for refracting light comprises a refractive element having a diffusion coated surface facing the solid state light emitting cells.

53. The light source of claim 43 wherein the means for refracting light is attached to the substrate.

54. The light source of claim 43 wherein the means for refracting light has a refractive index different from air.

55. The light source of claim 43 wherein the means for refracting light comprises a refractive element having a partially spherical shape positioned over the solid state light emitting cells.

56. The light source of claim 55 wherein the partially spherical shape of the refractive element is greater than a hemisphere but less than a full sphere.

57. A light source, comprising:
a substrate;
a plurality of solid state light emitting cells on the substrate; the solid state light emitting cells comprising first and second sets of solid state light emitting cells, wherein each of the solid state light emitting cells in the first set includes a phosphor layer and each of the solid state light emitting cells in the second set does not include a phosphor layer; and
a refractive element arranged with the solid state light emitting cells to mix the light emitted from the first and second sets of solid state light emitting cells.

58. The light source of claim 57 wherein each of the light emitting cells in the first set comprises a blue LED and each of the light emitting cells in the second set comprises an LED having that emits a longer wavelength than the blue LEDs.

59. The light source of claim 58 wherein each of the light emitting cells in the second set comprises a red, red-orange, orange or amber LED.

60. The light source of claim 58 wherein the refractive element is arranged with the solid state light emitting cells so that light emitted from the light source has a substantially spherical emission pattern.

61. The light source of claim 58 further comprising a boundary on the substrate, wherein the solid state light emitting cells is arranged within the interior of the boundary, the light source further comprising phosphor deposited within the interior of the boundary.

62. The light source of claim 58 wherein the refractive element comprises a surface facing the solid state light emitting cells and a phosphor layer on the surface.

63. The light source of claim 58 wherein the refractive element comprises a diffusion coated surface facing the solid state light emitting cells.

64. The light source of claim 58 wherein the refractive element is attached to the substrate.

65. The light source of claim 58 wherein the refractive element has a refractive index different from air.

66. The light source of claim 58 wherein the refractive element has a partially spherical shape positioned over the solid state light emitting cells.

67. The light source of claim 66 wherein the partially spherical shape of the refractive element is greater than a hemisphere but less than a full sphere.

68. A lamp, comprising:
a housing having a base and a transparent bulb portion mounted to the base; and
a light source within the housing, the light source comprising:
a substrate;
a plurality of solid state light emitting cells having a planar arrangement on the substrate; and
a refractive element arranged with the solid state light emitting cells so that light emitted from the light source has a substantially spherical emission pattern.

69. The lamp of claim 68 further comprising phosphor arranged with the solid state light emitting cells so that the light emitted from the transparent bulb portion is white light.

70. The lamp of claim 68 wherein each of the solid state light emitting cells includes a phosphor layer.

71. The lamp of claim 68 wherein the light source further comprises a boundary on the substrate, wherein the solid state light emitting cells is arranged within the interior of the boundary, the light source further comprising phosphor deposited within the interior of the boundary.

72. The lamp of claim 68 wherein the solid state light emitting cells comprises first and second sets of solid state light emitting cells, wherein each of the solid state light emitting cells in the first set includes a phosphor layer and each of the solid state light emitting cells in the second set does not include a phosphor layer.

73. The lamp of claim 72 wherein the refractive element is arranged with the solid state light emitting cells to mix the light emitted from the first and second sets of solid state light emitting cells.

74. The lamp of claim 72 wherein each of the light emitting cells in the first set comprises a blue LED and each of the light emitting cells in the second set comprises an LED having that emits a longer wavelength than the blue LEDs.

75. The lamp of claim 74 wherein each of the light emitting cells in the second set comprises a red, red-orange, orange or amber LED.

76. The lamp of claim 68 wherein the refractive element comprises a surface facing the solid state light emitting cells and a phosphor layer on the surface.

77. The lamp of claim 68 wherein the refractive element comprises a diffusion coated surface facing the solid state light emitting cells.

78. The lamp of claim 68 wherein the refractive element is attached to the substrate.

79. The lamp of claim 68 wherein the refractive element has a refractive index different from air.

80. The lamp of claim 68 wherein the refractive element has a partially spherical shape positioned over the solid state light emitting cells.

81. The lamp of claim 80 wherein the partially spherical shape of the refractive element is greater than a hemisphere but less than a full sphere.

82. The lamp of claim 68 further comprising a fan arranged within the housing to cool the solid state light emitting cells.

83. The lamp of claim 68 wherein the base is configured to electrically and mechanically mate with a lamp socket.

84. The lamp of claim 68 wherein the base comprises electrical contacts coupled to the solid state light emitting cells.

85. The lamp of claim 84 wherein the base comprises a cap configured to mechanically mate with the lamp socket, the cap comprising one of the electrical contacts.

86. The lamp of claim 85 wherein the base further comprises a tip having another one of the electrical contacts.

87. The lamp of claim 85 wherein the cap comprises a screw cap.

88. A lamp, comprising:
a housing having a base and a transparent bulb portion mounted to the base;
a light source within the housing, the light source comprising a plurality of solid state light emitting cells and a refractive element arranged with the solid state light emitting cells so that light emitted from the light source has a substantially spherical emission pattern; and
means for cooling the light source.

89. The lamp of claim 88 wherein the means for cooling the light source comprises a fan arranged within the housing to cool the solid state light emitting cells.

90. The lamp of claim 89 wherein the fan comprises an electronic fan.

91. The lamp of claim 88 wherein the means for cooling the light source comprises one or more heat pipes supporting the light source.

92. The lamp of claim 91 wherein the means for cooling the light source further comprises a plurality of spaced apart thermally conductive plates in the base, wherein the one or more heat pipes are arranged with the plates to dissipate heat generated by the solid state light emitting cells.

93. The lamp of claim 91 wherein the means for cooling the light source further comprises a plurality of spaced apart thermally conductive plates in the base, wherein the one or more heat pipes extend through the plates.

94. The lamp of claim 91 wherein the means for cooling the light source further comprises one or more vents in the base, wherein the one or more heat pipes are arranged with the vents to dissipate heat generated by the one or more solid state light emitting cells.

95. The lamp of claim 88 wherein the light source further comprises a substrate, the solid state light emitting cells having a planar arrangement on the substrate.

96. The lamp of claim 88 wherein the light source further comprises a substrate, the solid state light emitting cells being arranged on the substrate to emit light in substantially the same direction.

97. The lamp of claim 88 wherein the light source further comprises a substrate, the solid state light emitting cells having a planar arrangement on the substrate, and wherein the refractive element is positioned over the solid state light emitting cells.

98. The lamp of claim 88 wherein the light source further comprises a substrate, the solid state light emitting being arranged on the substrate, and wherein the solid state light emitting cells comprises first and second sets of solid state light emitting cells, and wherein each of the solid state light emitting cells in the first set includes a phosphor layer and each of the solid state light emitting cells in the second set does not include a phosphor layer; and wherein the refractive element is arranged with the solid state light emitting cells to mix the light emitted from the first and second sets of solid state light emitting cells.
